(19) United States
(12) Patent Application Publication
(10) Pub. No.: US 2026/0057949 A1
(43) Pub. Date: Feb. 26, 2026

(54) MEMORY STORAGE DEVICE AND READING METHOD THEREOF

(71) Applicant: Winbond Electronics Corp., Taichung City (TW)

(72) Inventor: Chung-Zen Chen, HsinChu (TW)

(73) Assignee: Winbond Electronics Corp., Taichung City (TW)

(21) Appl. No.: 19/091,814

(22) Filed: Mar. 26, 2025

(30) Foreign Application Priority Data
Aug. 20, 2024 (TW) 113131339

(51) Int. Cl. G11C 16/34; G11C 16/26; G11C 16/32

(52) U.S. Cl. CPC G11C 16/3418; G11C 16/26; G11C 16/32

(57) ABSTRACT

A memory storage device including a memory cell array and a controller circuit is provided. The memory cell array includes signature memory cells and option memory cells. The controller circuit is coupled to the memory cell array. The controller circuit is configured to read the signature memory cells and the option memory cells at the same time. When the reading of the signature memory cells passes, the controller circuit determines that the reading of the option memory cells passes.

### CROSS-REFERENCE TO RELATED APPLICATION

This application claims the priority benefit of Taiwan application serial no. 113131339, filed on Aug. 20, 2024. The entirety of the above-mentioned patent application is hereby incorporated by reference herein and made a part of this specification.

### BACKGROUND

### Technical Field

The disclosure relates to an electronic device and an operating method thereof, and particularly relates to a memory storage device and a reading method thereof.

### Description of Related Art

Taking a flash memory as an example, when reading a memory cell array, a controller circuit will first read one of the memory cells. After the reading of the memory cell passes, the controller circuit will start reading other memory cells. However, such a reading method may cause the problem that the memory cell read first passes, but when other memory cells are subsequently read, the reading fails due to the influence of power noise and power drop.

### SUMMARY

The disclosure provides a memory storage device and a reading method thereof, which may correctly read memory cells.

A memory storage device of the disclosure includes a memory cell array and a controller circuit. The memory cell array includes signature memory cells and option memory cells. The controller circuit is coupled to the memory cell array. The controller circuit is configured to read the signature memory cells and the option memory cells at the same time. When the reading of the signature memory cells passes, the controller circuit determines that the reading of the option memory cells passes.

A reading method of the memory storage device of the disclosure includes the following steps. A word line signal is applied to a word line to read signature memory cells and option memory cells at the same time. The signature memory cells and the option memory cells are located on the word line. It is determined whether the reading of the signature memory cells passes. When the reading of the signature memory cells passes, it is determined that the reading of the option memory cells passes.

### BRIEF DESCRIPTION OF THE DRAWINGS

FIG. 1 is a schematic block diagram of a memory storage device according to an embodiment of the disclosure.

FIG. 2 is a schematic block diagram of a memory storage device according to another embodiment of the disclosure.

FIG. 3A is a schematic outline diagram of the memory cell array according to the embodiment of FIG. 2.

FIG. 3B is a schematic outline diagram of a memory cell array according to another embodiment of the disclosure.

FIG. 4 is a schematic waveform diagram of word line signals and address signals according to an embodiment of the disclosure.

FIG. 5 is a flowchart of steps of a reading method of a memory storage device according to an embodiment of the disclosure.

FIG. 6 is a schematic waveform diagram of word line signals and address signals according to another embodiment of the disclosure.

FIG. 7 is a flowchart of steps of a reading method of a memory storage device according to another embodiment of the disclosure.

### DESCRIPTION OF THE EMBODIMENTS

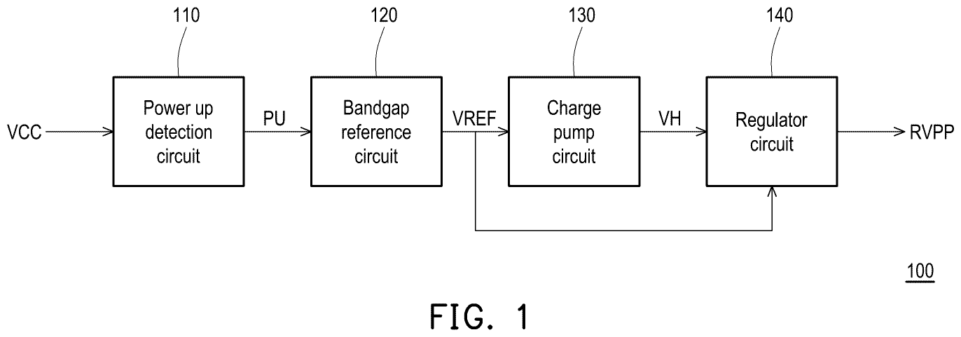

Taking a flash memory as an example, FIG. 1 illustrates the power on sequence of a memory storage device 100. First, a power up detection circuit 110 detects a power supply VCC and outputs a power up signal PU accordingly. The power up signal PU is used to start a bandgap reference circuit 120 to generate a reference voltage VREF to a charge pump circuit 130 and a regulator circuit 140. The charge pump circuit 130 generates a high voltage signal VH according to the reference voltage VREF. Then, the regulator circuit 140 generates a voltage signal RVPP according to the reference voltage VREF and the high voltage signal VH. The voltage signal RVPP may be provided to the word line decoder circuit as an operating voltage.

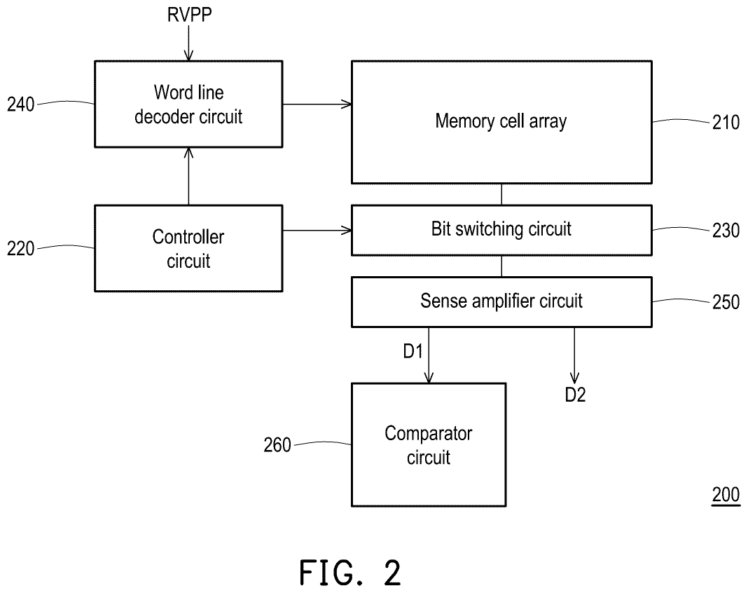

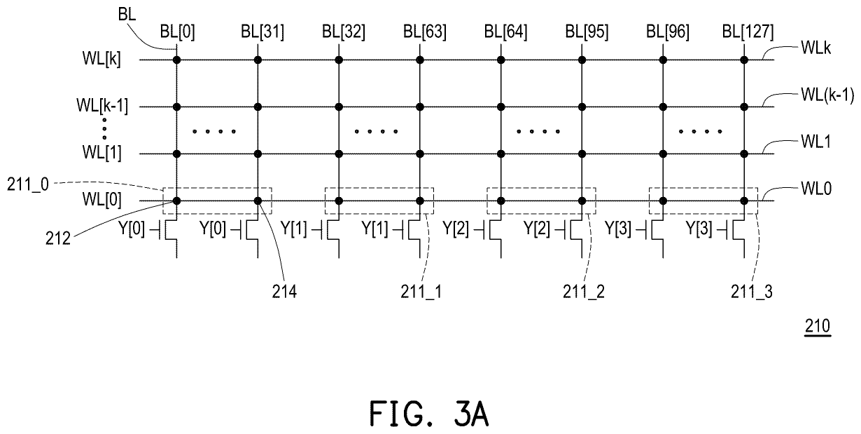

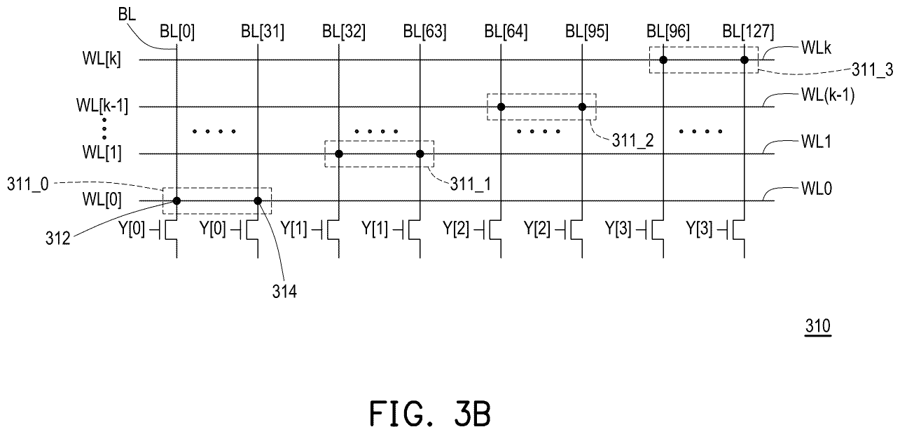

Referring to FIG. 2 and FIG. 3A, a memory storage device 200 includes a memory cell array 210, a controller circuit 220, a bit switching circuit 230, a word line decoder circuit 240, a sense amplifier circuit 250, and a comparator circuit 260. The controller circuit 220 is coupled to memory cell array 210.

The memory cell array 210 includes a plurality of signature memory cells 212 and a plurality of option memory cells 214. Taking a word line WL0 as an example, a memory cell group 211_0 corresponding to a same address signal Y[0] includes N memory cells, of which M memory cells are the signature memory cells 212 and N-M memory cells are the option memory cells 214. M and N are positive integers, and M<N. In an embodiment, the memory cell group 211_0 includes 32 memory cells, of which 4 memory cells are the signature memory cells and 28 memory cells are the option memory cells. Or, in another embodiment, the memory cell group 211_0 includes 32 memory cells, of which 8 memory cells are the signature memory cells and 24 memory cells are the option memory cells. Memory cell groups 211_1, 211_2, and 211_3 corresponding to address signals Y[1], Y[2], and Y[3] may be deduced in the same way. The number of the above memory cells and address signals is not intended to limit the disclosure. The signature memory cell 212 is configured, for example, to store specific data. The specific data must be read during power-up. Typically, applying the appropriate read voltage during a power on read operation ensures that correct data is read.

Therefore, when the word line WL0 is enabled, the signature memory cells 212 and the option memory cells 214 selected by the address signals Y[0] to Y[3] may be read at the same time. Similarly, when the remaining word lines WL1 to WLk are enabled, the signature memory cells 212 and the option memory cells 214 selected by the address signals Y[0] to Y[3] are also read at the same time. The number of the above word lines is not intended to limit the disclosure.

The word line decoder circuit 240 is coupled to the memory cell array 210 through the plurality of word lines WL0 to WLk. The word line decoder circuit 240 is configured to output a plurality of word line signals WL[0] to WL[k] to respectively enable the corresponding word lines WL0 to WLk. The controller circuit 220 may control the word line decoder circuit 240 to output the word line signal, so as to apply the word line signal to the corresponding word line. For example, the memory storage device 200 may utilize the power on sequence of FIG. 1 to generate the voltage signal RVPP to the word line decoder circuit 240 as an operating voltage. The bit switching circuit 230 is coupled to the memory cell array 210 through a bit line BL. The controller circuit 220 is configured to output the address signals Y[0] to Y[3] to select the memory cells to be read.

The layout of the memory cell array 210 of FIG. 3A is not intended to limit the disclosure. Referring to FIG. 3B, FIG. 3B illustrates a layout of another memory cell array 310. The memory cell array 310 includes memory cell groups 311_0, 311_1, 311_2, and 311_3 corresponding to address signals Y[0], Y[1], Y[2], and Y[3]. Each memory cell group includes a plurality of signature memory cells 312 and option memory cells 314. In FIG. 3B, the memory cell groups on each word line do not correspond to a same address signal. For example, the memory cell group 311_0 on the word line WL0 corresponds to the address signal Y[0], and the memory cell group 311_1 on the word line WL1 corresponds to the address signal Y[1].

In the embodiment, when the word line WL0 is enabled, the signature memory cells 312 and the option memory cells 314 selected by the address signal Y[0] are read at the same time. When the word line WL1 is enabled, the signature memory cells 312 and the option memory cells 314 selected by the address signal Y[1] are also read at the same time. Corresponding to the reading situation when other word lines are enabled, the same may be deduced.

The layout of the memory cell arrays 210 and 310 of FIG. 3A and FIG. 3B is only used for illustration and is not intended to limit the disclosure. The distribution of the memory cell groups in the memory cell array may be any combination of FIG. 3A and FIG. 3B, that is, each word line may have one or more memory cell groups. The layout of the memory cell arrays 210 and 310 of FIG. 3A and FIG. 3B are only two possible exemplary embodiments.

Regarding the hardware structure of the components in FIG. 1 and FIG. 2, the controller circuit 220 may be a processor with computational capabilities. As another option, the controller circuit 220 may be designed using hardware description languages (HDL) or any other design methods for digital circuits familiar to people skilled in the art and may be hardware circuits implemented through a field programmable gate array (FPGA), a complex programmable logic device (CPLD), or an application-specific integrated circuit (ASIC). In addition, enough teaching, suggestion, and implementation illustration for hardware structures of the word line decoder circuit 240, the sense amplifier circuit 250, and the comparator circuit 260 may be obtained with reference to common knowledge in the related art.

In addition, in FIG. 3A and FIG. 3B, the numbers of the word lines, the bit lines, the memory cells, and the memory cell groups are only used for illustration and are not intended to limit the disclosure.

Referring to FIG. 2 to FIG. 4, the controller circuit 220 reads data D1 and D2 of the signature memory cells 212 and the option memory cells 214 located on a same word line at the same time during the power up reading period until the reading of the signature memory cells 212 passes.

Specifically, the controller circuit 220 reads the data D1 of the signature memory cells 212 during the power up reading period, and senses the data D1 by the sense amplifier circuit 250. Then, the comparator circuit 260 determines whether the read data D1 is correct. If the read data D1 is correct, it indicates that the reading of the signature memory cells 212 passes. On the contrary, if the read data D1 is incorrect, it indicates that the reading of the signature memory cells 212 fails.

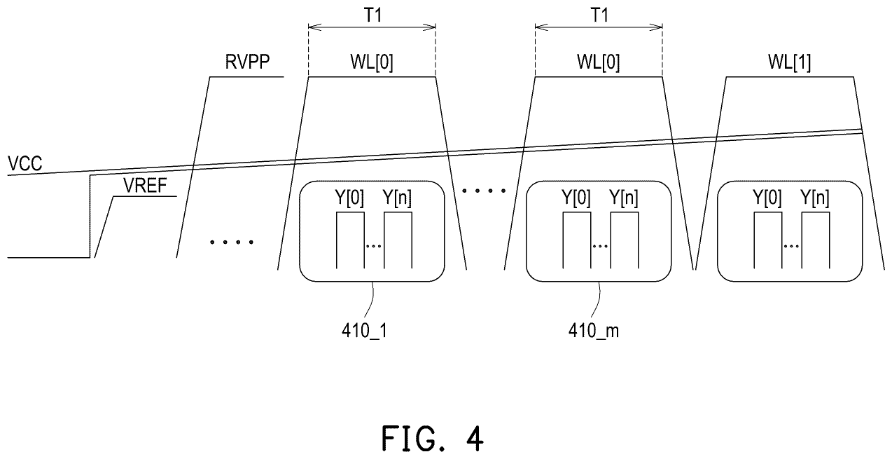

In FIG. 4, the word line decoder circuit 240 outputs the word line signals WL[0] and WL[1] to turn on the word lines WL0 and WL1. The rest of the word line signals may be deduced in the same way. Turning on the word line means that the word line signal applied to the word line is an enabling period, such as a high level or a low level period. In FIG. 4, the high level periods of the word line signals WL[0] and WL[1] are enabling periods.

Taking the first word line WL0 of FIG. 3A as an example, the signature memory cells 212 and the option memory cells 214 are located on the first word line WL0. The controller circuit 220 is configured to apply the first word line signal WL[0] to the first word line WL0 to read the data D1 and D2 of the signature memory cells 212 and the option memory cells 214 at the same time multiple times until the reading of the signature memory cells 212 passes.

The first word line signal WL[0] includes a plurality of enabling periods T1. The enabling periods T1 have a same time length. In each enabling period T1, the controller circuit 220 will successively output address signals Y[0] to Y[n] to read the data D1 and D2 of the read signature memory cells 212 and option memory cells 214 located on the first word line WL0. In addition, in FIG. 4, the address signals Y[0] to Y[n] have the same width, where n is an integer greater than 0.

In the embodiment, the controller circuit 220 toggles the first word line signal WL[0] multiple times to read data, which means that when the reading of the signature memory cells 212 fails, the first word line signal WL[0] will be turned on again. That is to say, the plurality of enabling periods T1 of the first word line signal WL[0] are not continuous, and the first word line WL0 is turned off between each reading. In FIG. 4, the controller circuit 220 performs a first reading 410_1 on the signature memory cells 212 and the option memory cells 214 on the first word line WL0 at the same time. As long as the reading of any signature memory cell 212 fails, the controller circuit 220 will turn on the first word line signal WL[0] again, and read the signature memory cells 212 and the option memory cells 214 on the first word line WL0 again. Then, in an m-th reading 410_m, the controller circuit 220 determines that the reading of the signature memory cells 212 passes, where m is an integer greater than 1. When the reading of the signature memory cells 212 passes, the controller circuit 220 will also determine that the reading of the option memory cells 214 passes. That is to say, the controller circuit 220 regards the data D2 read from the option memory cells 214 as correct.

Then, when the reading of the signature memory cells 212 on the first word line WL0 passes, the controller circuit 220 applies the second word line signal WL[1] to the second word line WL1 to read the data D1 and D2 of the signature memory cells 212 and the option memory cells 214 located on the second word line WL1. The way the controller circuit 220 reads the memory cells on the other word lines may be deduced in the same way.

Referring to FIG. 2 to FIG. 5, the reading method of the memory storage device of the embodiment is at least suitable for the memory storage device 200 of FIG. 2, but the disclosure is not limited thereto.

Taking the memory storage device 200 as an example, in step S100, the controller circuit 220 applies the first word line signal WL[0] to the first word line WL0 to read the data D1 and D2 of the signature memory cells 212 and the option memory cells 214 at the same time. In step S110, the controller circuit 220 determines whether the reading of the signature memory cells 212 passes. If the read data D1 is correct, it indicates that the reading of the signature memory cells 212 passes, and the reading method will execute step S120. In step S120, the controller circuit 220 also determines that the reading of the option memory cells 214 passes, indicating that the data D2 read from the option memory cells 214 is regarded as correct.

On the contrary, if the data D1 read is incorrect, it indicates that the reading of the signature memory cells 212 fails, and returns to step S100 of the reading method. The controller circuit 220 toggles the first word line signal WL[0] in step S130 to return to step S100 to read the data D1 and D2 of the signature memory cells 212 and the option memory cells 214 at the same time again until the reading of the signature memory cells 212 passes.

In addition, the reading method of the memory storage device of the embodiment of the disclosure may obtain enough teaching, suggestion, and implementation illustration from the description of the embodiment in FIG. 1 to FIG. 4, and therefore will not be repeated.

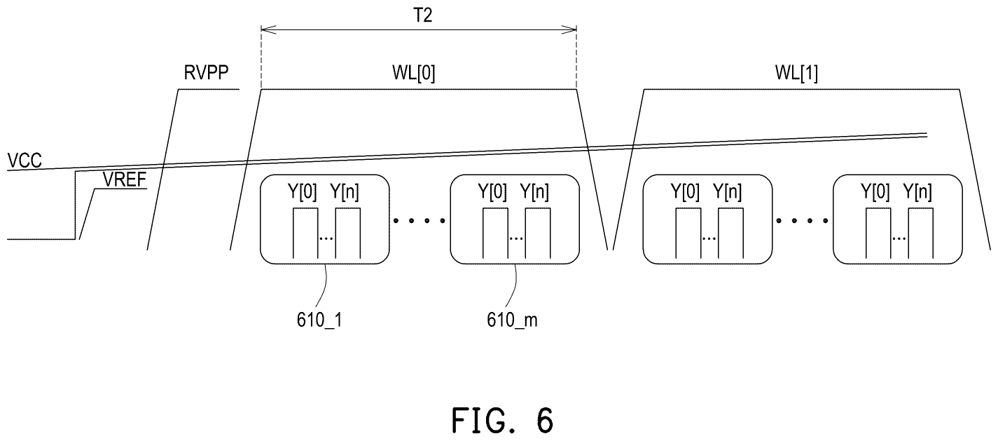

FIG. 6 is a schematic waveform diagram of word line signals and address signals according to another embodiment of the disclosure. Referring to FIG. 2, FIG. 3A, and FIG. 6, in FIG. 6, the word line decoder circuit 240 outputs the word line signals WL[0] and WL[1] to turn on the word lines WL0 and WL1. The rest of the word line signals may be deduced in the same way. Turning on the word line means that the word line signal applied to the word line is an enabling period, such as a high level or a low level period. In FIG. 6, the high level periods of the word line signals WL[0] and WL[1] are enabling periods.

Taking the first word line WL0 of FIG. 3A as an example, the signature memory cells 212 and the option memory cells 214 are located on the first word line WL0. The controller circuit 220 applies the first word line signal WL[0] to the first word line WL0 to read the data D1 and D2 of the signature memory cells 212 and the option memory cells 214 at the same time multiple times during the enabling period T2 until the reading of the signature memory cells 212 passes.

In the embodiment, the controller circuit 220 performs multiple readings 610_1 and 610_m on the first word line WL0. During an m-th reading, the controller circuit 220 determines that the reading of the signature memory cells 212 passes. Between each reading, the first word line signal WL0 remains in an enabled state and does not toggle. That is to say, the single enabling period T2 of the first word line signal WL[0] is continuous, and between each reading, the first word line WL0 will not be turned on again but will continue to remain in an on state.

Then, when the reading of the signature memory cells 212 on the first word line WL0 passes, the controller circuit 220 applies the second word line signal WL[1] to the second word line WL1 to read the data D1 and D2 of the signature memory cells 212 and the option memory cells 214 until the reading of the signature memory cells 212 located on the second word line WL1 passes. Between each reading, the second word line signal WL[1] also remains in an enabled state and does not toggle. The way the controller circuit 220 reads the memory cells on the other word lines may be deduced in the same way.

In the embodiment of FIG. 6, since the word line signal is not toggled and remains in an enabled state between each reading, the power of the voltage signal RVPP may be saved. Moreover, since the power noise and the power drop are reduced, the reading of the memory cells may pass more easily.

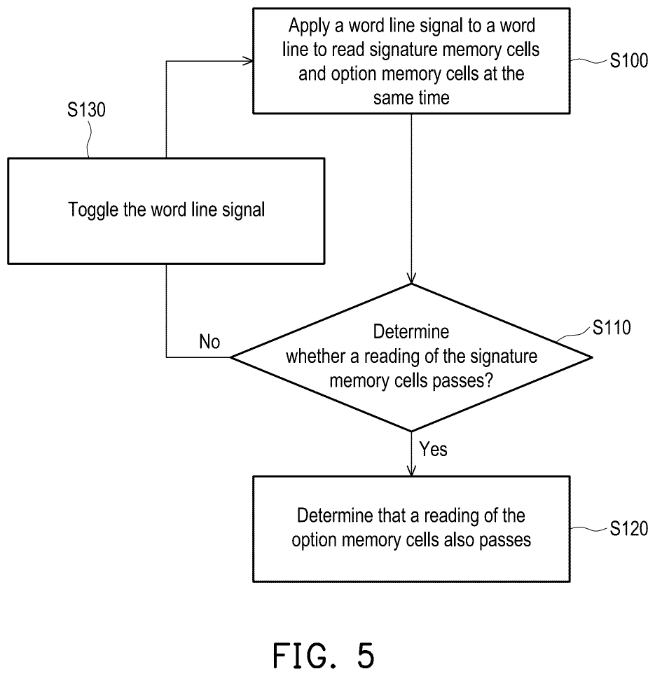

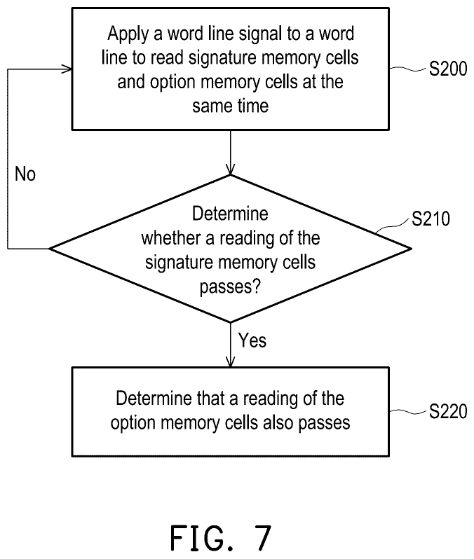

Referring to FIG. 2, FIG. 3A, FIG. 6, and FIG. 7, the reading method of the memory storage device of the embodiment is at least suitable for the memory storage device 200 of FIG. 2, but the disclosure is not limited thereto. Taking the memory storage device 200 as an example, steps S200, S210, and S220 are similar to the embodiment of FIG. 5. However, in the embodiment, between each reading, the word line signals WL[0] and WL[1] remain in an enabled state.

In addition, the reading method of the memory storage device of the embodiment of the disclosure may obtain enough teaching, suggestion, and implementation illustration from the description of the embodiment in FIG. 1 to FIG. 3A and FIG. 6, and therefore will not be repeated.

To sum up, in the embodiment of the disclosure, the controller circuit may read the signature memory cells and the option memory cells at the same time until the reading of the signature memory cells passes. When the reading of the signature memory cells passes, the controller circuit will also determine that the reading of the option memory cells passes. In this way, the controller circuit may correctly read the option memory cells and reduce the influence of power noise and power drop on the reading results. In addition, the controller circuit may toggle the word line signal and perform readings during an enabling period thereof, or the controller circuit may not toggle the word line signal but maintain the word line signal in an enabled state and perform multiple readings.

Although the disclosure has been described with reference to the embodiments above, the embodiments are not intended to limit the disclosure. Any person skilled in the art can make some changes and modifications without departing from the spirit and scope of the disclosure. Therefore, the scope of the disclosure will be defined in the appended claims.

What is claimed is:

1. A memory storage device, comprising:
a memory cell array, comprising signature memory cells and option memory cells; and
a controller circuit, coupled to the memory cell array, and configured to read the signature memory cells and the option memory cells at a same time, wherein when a reading of the signature memory cells passes, the controller circuit determines that a reading of the option memory cells passes.

2. The memory storage device according to claim 1, wherein the signature memory cells and the option memory cells are located on a same word line, and the controller circuit is configured to apply a word line signal to the word line to read the signature memory cells and the option memory cells at the same time.

3. The memory storage device according to claim 2, wherein the controller circuit reads the signature memory cells and the option memory cells at the same time multiple times until the reading of the signature memory cells passes.

4. The memory storage device according to claim 2, wherein the word line signal comprises a plurality of enabling periods, and the controller circuit reads the signature memory cells and the option memory cells at the same time in each enabling period of the plurality of enabling periods.

5. The memory storage device according to claim 4, wherein the plurality of enabling periods of the word line signal have a same time length.

6. The memory storage device according to claim 2, wherein the word line signal comprises a single enabling period, and the controller circuit reads the signature memory cells and the option memory cells at the same time during the single enabling period.

7. The memory storage device according to claim 1, wherein the controller circuit reads the signature memory cells and the option memory cells at the same time during a power up reading period.

8. A reading method of a memory storage device, wherein the memory storage device comprises a memory cell array, and the memory cell array comprises signature memory cells and option memory cells, the reading method of the memory storage device comprising:
applying a word line signal to a word line to read the signature memory cells and the option memory cells at a same time, wherein the signature memory cells and the option memory cells are located on the word line;
determining whether a reading of the signature memory cells passes; and
when the reading of the signature memory cells passes, determining that a reading of the option memory cells also passes.

9. The reading method of the memory storage device according to claim 8, further comprising:
when the reading of the signature memory cells fails, reading the signature memory cells and the option memory cells at the same time again until the reading of the signature memory cells passes.

10. The reading method of the memory storage device according to claim 8, wherein the word line signal comprises a plurality of enabling periods, and the signature memory cells and the option memory cells are read at the same time in each enabling period of the plurality of enabling periods.

11. The reading method of the memory storage device according to claim 10, wherein the plurality of enabling periods of the word line signal have a same time length.

12. The reading method of the memory storage device according to claim 8, wherein the word line signal comprises a single enabling period, and the signature memory cells and the option memory cells are read at the same time during the single enabling period.
